(19) United States
(12) Patent Application Publication
(10) Pub. No.: US 2024/0145259 A1
(43) Pub. Date: May 2, 2024

(54) SOLDER REFLOW APPARATUS AND SOLDER REFLOW METHOD

(71) Applicant: SAMSUNG ELECTRONICS CO., LTD., Suwon-si (KR)

(72) Inventor: Youngja KIM, Suwon-si (KR)

(21) Appl. No.: 18/201,932

(22) Filed: May 25, 2023

(30) Foreign Application Priority Data
Oct. 26, 2022 (KR) 10-2022-0138837

(51) Int. Cl. H01L 21/60; H01L 21/677; H01L 21/687

(52) U.S. Cl. CPC H01L 21/60; H01L 21/67778; H01L 21/68764; H01L 2021/6003; H01L 2021/60135

(57) ABSTRACT

A solder reflow apparatus may include a reflow chamber receiving a heat transfer fluid. The heat transfer fluid transfers heat to a solder for mounting an electronic part on a substrate. A heater heats the heat transfer fluid in the reflow chamber. A rail is arranged in an upper region of the reflow chamber and extends along a horizontal direction. A stage module may be movably connected to the rail and supports the substrate. The controller controls a positioning of the stage module to move the substrate supported by the stage module to different heights in a vertical direction.

### CROSS-REFERENCE TO RELATED APPLICATION

This application claims priority under 35 U.S.C. § 119 to Korean Patent Application No. 10-2022-0138837, filed on Oct. 26, 2022 in the Korean Intellectual Property Office, the disclosure of which is incorporated by reference in its entirety herein.

### 1. TECHNICAL FIELD

Embodiments of the present disclosure relate to a solder reflow apparatus and a solder reflow method. More particularly, embodiments of the present disclosure relate to a solder reflow apparatus using a vapor phase soldering and a solder reflow method using the solder reflow apparatus.

### 2. DISCUSSION OF RELATED ART

In a surface mount technology, a convection reflow, a laser assisted bonding, a vapor phase soldering, etc., may be used for soldering a solder paste. In the vapor phase soldering process, a heated heat transfer fluid may transfer heat to a solder for mounting an electronic part such as a semiconductor chip on a substrate. After transferring the heat, the heat transfer fluid may be condensed to form a liquid.

In some manufacturing processes, the solder reflow apparatus may be configured to perform the solder reflow process on one substrate at a time. Thus, after completing the solder reflow process with respect to a substrate (e.g., a previous substrate), the solder reflow process may be performed subsequently on a different substrate (e.g., a following substrate). As a result, the solder reflow process may have a relatively low productivity and process efficiency.

### SUMMARY

Example embodiments provide a solder reflow apparatus having increased productivity.

Example embodiments also provide a solder reflow method using the above-mentioned solder reflow apparatus

According to an embodiment of the present disclosure, a solder reflow apparatus may include a reflow chamber receiving a heat transfer fluid. The heat transfer fluid transfers heat to a solder for mounting an electronic part on a substrate. A heater heats the heat transfer fluid in the reflow chamber. A rail is arranged in an upper region of the reflow chamber and extends along a horizontal direction. A stage module may be movably connected to the rail and supports the substrate. The controller controls a positioning of the stage module to move the substrate supported by the stage module to different heights in a vertical direction.

According to an embodiment of the present disclosure, a solder reflow apparatus includes a reflow chamber having a plurality of sub-chambers. Each of the plurality of sub-chambers receives a heat transfer fluid to independently perform a solder reflow process. The heat transfer fluid transfers heat to a solder for mounting an electronic part on a substrate. Heaters heat the heat transfer fluid in the plurality of sub-chambers, respectively. Stage modules are arranged in the plurality of sub-chambers, respectively. The stage modules support the substrate. A loading gate loads the substrate into the plurality of sub-chambers. An unloading gate unloads the substrate from the plurality of sub-chambers. An unloading passage extends between the loading gate and the unloading gate.

According to an embodiment of the present disclosure, a solder reflow method includes heating a heat transfer fluid in a reflow chamber. The heat transfer fluid transfers heat to a solder for mounting an electronic part on a substrate. The substrate is positioned with the solder at a first height in a first region of the reflow chamber to perform a first process of dipping the solder into the heat transfer fluid. The substrate is positioned at a second height lower than the first height in a second region of the reflow chamber to perform a second process of pre-heating the solder. The substrate is positioned at a third height lower than the second height in a third region of the reflow chamber to perform a third process of reflowing the solder.

According to an embodiment of the present disclosure, the reflow chamber may be divided into a plurality of the regions. The stage module may sequentially transfer a previous substrate along the rail. Thus, the first to third processes in the reflow process may be sequentially performed on the previous substrate. During the reflow process of the previous substrate, a following substrate may be loaded into the reflow chamber through the rail. Therefore, the reflow process may be performed on the following substrate simultaneously with the performing of the reflow process on the previous substrate. As a result, the solder reflow process may have increased productivity by decreasing a time of the solder reflow process.

### BRIEF DESCRIPTION OF THE DRAWINGS

Embodiments of the present disclosure will be more clearly understood from the following detailed description taken in conjunction with the accompanying drawings. FIGS. 1 to 7 represent non-limiting, example embodiments of the present disclosure as described herein.

FIG. 1 is a cross-sectional view illustrating a solder reflow apparatus in accordance with an embodiment of the present disclosure;

FIGS. 2 to 4 are cross-sectional views illustrating an operation of the solder reflow apparatus in FIG. 1 according to embodiments of the present disclosure:

FIG. 5 is a flow chart illustrating a solder reflow method using the solder reflow apparatus in FIG. 1 according to an embodiment of the present disclosure;

FIG. 6 is a timing chart illustrating the solder reflow method in FIG. 5 according to an embodiment of the present disclosure; and

FIG. 7 is a cross-sectional view illustrating a solder reflow apparatus in accordance with an embodiment of the present disclosure.

### DETAILED DESCRIPTION OF EMBODIMENTS

Hereinafter, embodiments of the present disclosure will be explained in detail with reference to the accompanying drawings.

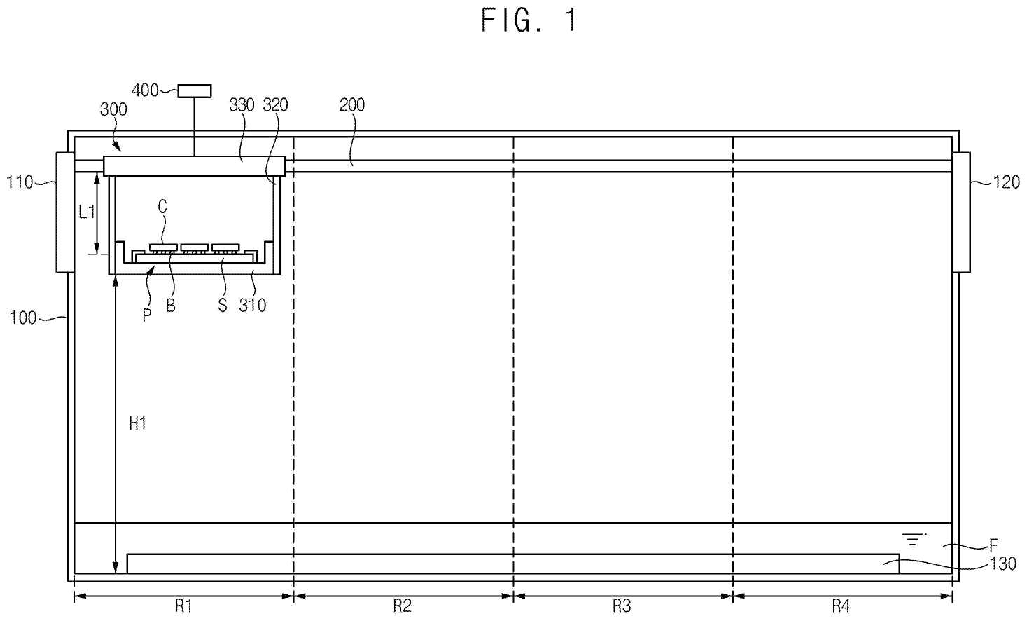

FIG. 1 is a cross-sectional view illustrating a solder reflow apparatus in accordance with an embodiment of the present disclosure.

Referring to FIG. 1, a solder reflow apparatus may be used for soldering an electronic part on a substrate to mount the electronic part on the substrate. For example, the solder reflow apparatus may be used for manufacturing a semiconductor package P. In an embodiment, the semiconductor package P may include a package substrate S, a semiconductor chip C, conductive bumps B, etc. The package substrate S may correspond to the substrate. The semiconductor chip C may correspond to the electronic part. The conductive bumps B may be interposed between the package substrate S and the semiconductor chip C. The conductive bumps B may be attached to the package substrate S and the semiconductor chip C by a soldering process performed by the solder reflow apparatus.

In an embodiment, the solder reflow apparatus may include a reflow chamber 100, a heater 130, a rail 200, a loading gate 110, an unloading gate 120, a stage module 300 and a controller 400. In an embodiment, the solder reflow apparatus may further include a temperature sensor configured to monitor a temperature in the reflow chamber 100.

In some embodiments, the solder reflow apparatus may correspond to a vapor phase soldering type apparatus configured for soldering a solder paste by a heated saturated vapor in the reflow chamber 100.

The reflow chamber 100 may include a reservoir configured to receive a heat transfer fluid F. In an embodiment as shown in FIG. 1, the reservoir may be a lower region in the reflow chamber 100. However, embodiments of the present disclosure are not necessarily limited thereto. The reflow chamber 100 may include a space filled with a gas generated by heating the heat transfer fluid F. The space may be a remaining space in the reflow chamber 100 except for the reservoir. The reflow chamber 100 may be extended in a vertical direction to have a height. The vapor generated by evaporating the heat transfer fluid F may be upwardly moved in the reflow chamber 100. The vapor may be condensed to form a liquid. The liquid may be downwardly moved in the reflow chamber 100. The liquid may then be collected in the reservoir.

In an embodiment, an internal pressure of the reflow chamber 100 may be an atmospheric pressure. Alternatively, the reflow chamber 100 may be connected to an exhaust apparatus such as a vacuum pump to adjust the internal pressure of the reflow chamber 100 from an atmospheric pressure. The internal pressure of the reflow chamber 100 may be maintained for changing a boiling point of the heat transfer fluid F or for soldering environments.

The heat transfer fluid F may be a chemical for providing the vapor required for the soldering. In an embodiment, the heat transfer fluid F may be selected in accordance with the boiling point of the heat transfer fluid F, environment influences, corrosiveness of the vapor, etc. The heat transfer fluid F may include an inert organic liquid. For example, in an embodiment the heat transfer fluid F may include a Galden solution in perfluoropolyether (PFPEs). The Galden solution may have a boiling point of about 230° C. However, embodiments of the present disclosure are not necessarily limited thereto.

The heater 130 may heat the heat transfer fluid F in the reflow chamber 100 to generate a saturated vapor. In an embodiment, the heater 130 may include an electrical resistor dipped into the heat transfer fluid F on a bottom surface of the reflow chamber 100. However, embodiments of the present disclosure are not necessarily limited thereto. For example, in an embodiment the heater 130 may include a coil-shaped resistor configured to surround the reservoir.

Additionally, a heater as a part of a temperature controller may be installed at a sidewall of the reflow chamber 100 to control internal temperatures of the reflow chamber 100.

The rail 200 may be horizontally arranged in the reflow chamber 100. For example, in an embodiment the rail 200 may be positioned in an upper region of the reflow chamber 100. The rail 200 may be connected between a first sidewall of the reflow chamber 100 and an opposite second sidewall of the reflow chamber 100.

In an embodiment, the loading gate 110 may be arranged at an upper portion of the first sidewall of the reflow chamber 100. However, embodiments of the present disclosure are not necessarily limited thereto. A first end of the rail 200 may be connected to the loading gate 110. The substrate S may be loaded into the reflow chamber 100 through the loading gate 110.

The unloading gate 120 may be arranged at an upper portion of the second sidewall of the reflow chamber 100. A second end of the rail 200 that is opposite to the first end of the rail may be connected to the unloading gate 120. The substrate S on which the solder reflow process may be performed may be unloaded from the reflow chamber 100 through the unloading gate 120.

In an embodiment, the solder reflow process may include a first process, a second process, a third process and a fourth process. The first process may include dipping the solder into the heat transfer fluid F at a first temperature T1. The second process may include pre-heating the solder at a second temperature T2. The third process may include reflowing the solder at a third temperature T3. The fourth process may include cooling the solder at a fourth temperature T4. The second temperature T2 may be higher than the first temperature T1. For example, in an embodiment the first temperature T1 may be in a range of about 25° C. to about 150° C. The second temperature T2 may be in a range of about 150° C. to about 200° C. The third temperature T3 may be higher than the second temperature T2. For example, in an embodiment the third temperature T3 may be in a range of about 200° C. to about 230° C. The fourth temperature T4 may be lower than the first temperature T1. For example, the fourth temperature T4 may be in a range of about 20° C. to about 30° C.

Therefore, an inner region of the reflow chamber 100 may be divided into first to fourth regions R1, R2, R3 and R4 by the first to fourth processes. The first to fourth regions R1, R2, R3 and R4 may be sequentially arranged in the horizontal direction. For example, the first region R1 may be positioned adjacent to the loading gate 110. The second region R2 may be positioned adjacent to the first region R1. The third region R3 may be positioned adjacent to the second region R2. The fourth region R4 may be positioned adjacent to the third region R3 and the unloading gate 120. Thus, the fourth region R4 may be located between the third region R3 and the unloading gate 120. The first process may be performed in the first region R1. The second process may be performed in the second region R2. The third process may be performed in the third region R3. The fourth process may be performed in the fourth region R4. In an embodiment, the division of the inner region of the reflow chamber 100 into the first to fourth regions R1, R2, R3 and R4 may be determined by heights of the stage module 300 illustrated later.

The stage module 300 may be movably connected to the rail 200. Thus, the stage module 300 may be moved in the reflow chamber 100 along the rail 200 in the horizontal direction (e.g., from the first end of the rail 200 to the second end of the rail 200).

The stage module 300 may include a stage 310, a vertical actuator 320 and a horizontal actuator 330. The stage 310 may be configured to support the substrate S. For example, in an embodiment the substrate S may be placed on an upper surface of the stage 310.

The vertical actuator 320 may be configured to move the stage 310 in a vertical direction. In an embodiment, the vertical actuator 320 may include a motor, a cylinder, etc. However, embodiments of the present disclosure are not necessarily limited thereto.

The horizontal actuator 330 may be connected to the vertical actuator 320. The horizontal actuator 330 may be movably connected to the rail 200 so that it may be moved along the rail 200. For example, the horizontal actuator 330 may be moved on the rail 200 in the horizontal direction. Since the stage 310 may be connected to the vertical actuator 320, the stage 310 may be moved by the horizontal actuator 330 in the horizontal direction. In an embodiment, the horizontal actuator 330 may include a motor, a cylinder, etc. However, embodiments of the present disclosure are not necessarily limited thereto.

The controller 400 may control operations of the vertical actuator 320 and the horizontal actuator 330. For example, in an embodiment the controller 400 may control the operation of the vertical actuator 320 to provide the stage 310 with various descent positions (e.g., with respect to the rail 200 positioned at an upper portion of the reflow chamber 100). For example, the controller 400 may control the movement of the stage 310 to heights measured from a bottom surface of the reflow chamber 100. In an embodiment, the controller 400 may provide the stage 310 with the different heights corresponding to the first to fourth regions R1, R2, R3 and R4.

For example, in an embodiment in the first region R1, the controller 400 may control the vertical actuator 320 to descend the stage 310 by a first length L1 from the rail 200. Thus, the stage 310 may be positioned at a first height H1 measured from the bottom surface of the reflow chamber 100 in response to the controller 400. In an embodiment, the reflow chamber 100 may have a gradually decreased temperature profile from bottom to top. Therefore, a temperature at the first height H1 may correspond to the first temperature T1. Thus, the first process may be performed on the solder at the first temperature T1 at the first height H1. For example, in an embodiment the solder may be dipped into the heat transfer fluid F at the first temperature T1.

After completing the first process, the controller 400 may control the horizontal actuator 330 to move the stage 310 from the first region R1 to the second region R2. In the second region R2, the controller 400 may control the vertical actuator 320 to descend the stage 310 by a second length L2 from the rail 200. In an embodiment, the second length L2 may be greater than the first length L1. Thus, the stage 310 may be positioned at a second height H2 measured from the bottom surface of the reflow chamber 100 in response to the controller 400. Since the second height H2 may be lower than the first height H1, a temperature at the second height H2 may correspond to the second temperature T2 that is higher than the first temperature T1. Thus, the second process may be performed on the solder at the second temperature T2. For example, in an embodiment the solder may be pre-heated at the second temperature T2.

After completing the second process, the controller 400 may control the horizontal actuator 330 to move the stage 310 from the second region R2 to the third region R3. In the third region R3, the controller 400 may control the vertical actuator 320 to descend the stage 310 by a third length L3 from the rail 200. In an embodiment, the third length L3 may be greater than the second length L2. Thus, the stage 310 may be positioned at a third height H3 measured from the bottom surface of the reflow chamber 100 in response to the controller 400. Since the third height H3 may be lower than the second height H2, a temperature at the third height H3 may correspond to the third temperature T3 that is higher than the second temperature T2. Thus, the third process may be performed on the solder at the third temperature T3. For example, in an embodiment the solder may be reflowed at the third temperature T3.

After completing the third process, the controller 400 may control the horizontal actuator 330 to move the stage 310 from the third region R3 to the fourth region R4. In the fourth region R4, the controller 400 may control the vertical actuator 320 to ascend the stage 310 by a fourth length L4 from the rail 200. In an embodiment, the fourth length L4 may be less than the first length L1. Thus, the stage 310 may be positioned at a fourth height H4 measured from the bottom surface of the reflow chamber 100. Since the fourth height H4 may be higher than the first height H1, a temperature at the fourth height H4 may correspond to the fourth temperature T4 that is lower than the first temperature T1. Thus, the fourth process may be performed on the solder at the fourth temperature T4. For example, in an embodiment the solder may be cooled at the fourth temperature T4.

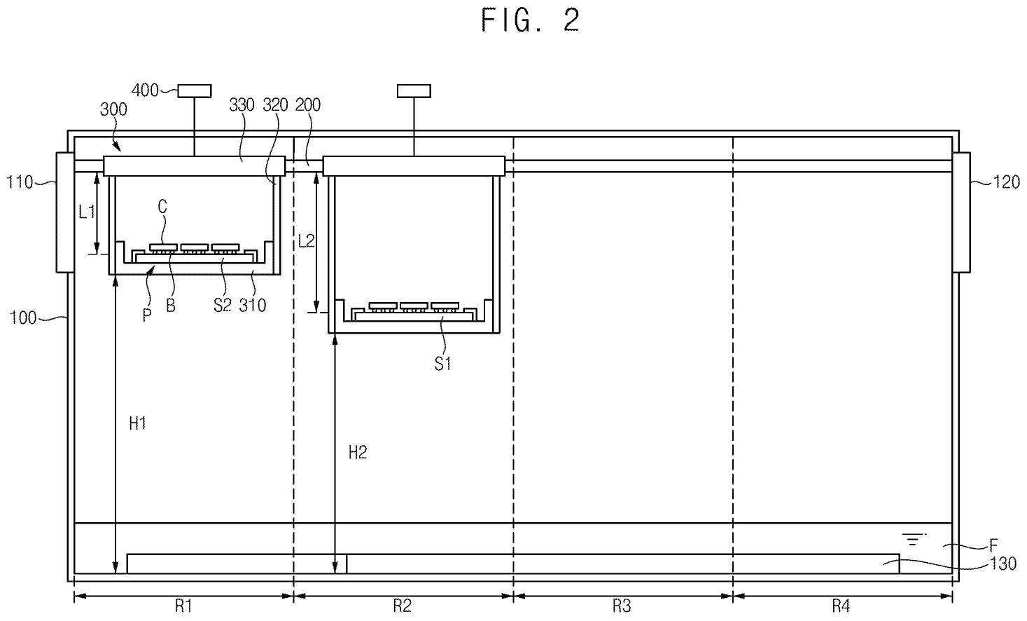

FIGS. 2 to 4 are cross-sectional views illustrating an operation of the solder reflow apparatus in FIG. 1.

Referring to FIG. 2, the first process may be performed on a first substrate S1 in the first region R1 at the first height H1. The first substrate S1 may then be moved from the first region R1 to the second region R2. The stage module 300 may transfer a second substrate S2 to the empty first region R1. Thus, in an embodiment, while the second process may be performed on the first substrate S1 in the second region R2, the first process may be simultaneously performed on the second substrate S2 in the first region R1.

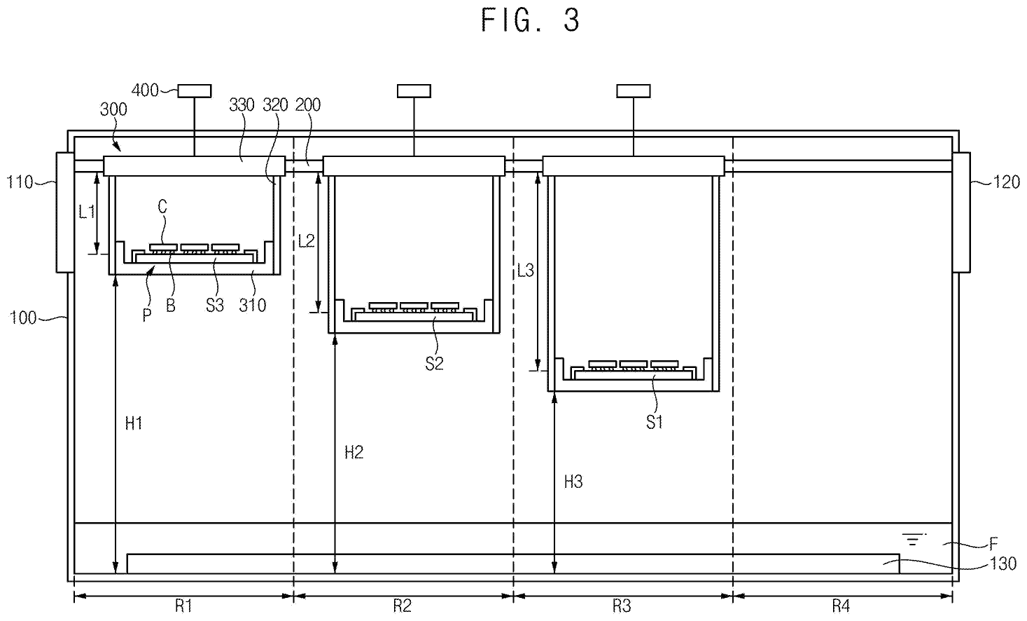

Referring to FIG. 3, after completing the second process on the first substrate S1 in the second region R2, the first substrate S1 may then be moved from the second region R2 to the third region R3. The second substrate S2 may be loaded into the empty second region R2. Thus, in an embodiment, while the third process may be performed on the first substrate S1 in the third region R3, the second process may be simultaneously performed on the second substrate S2 in the second region R2.

Further, the stage module 300 may load a third substrate S3 into the empty first region R1. Thus, in an embodiment, while the second process may be performed on the second substrate S2 in the second region R2 and the third process may be performed on the first substrate S1 in the third region R3, the first process may be simultaneously performed on the third substrate S3 in the first region R1.

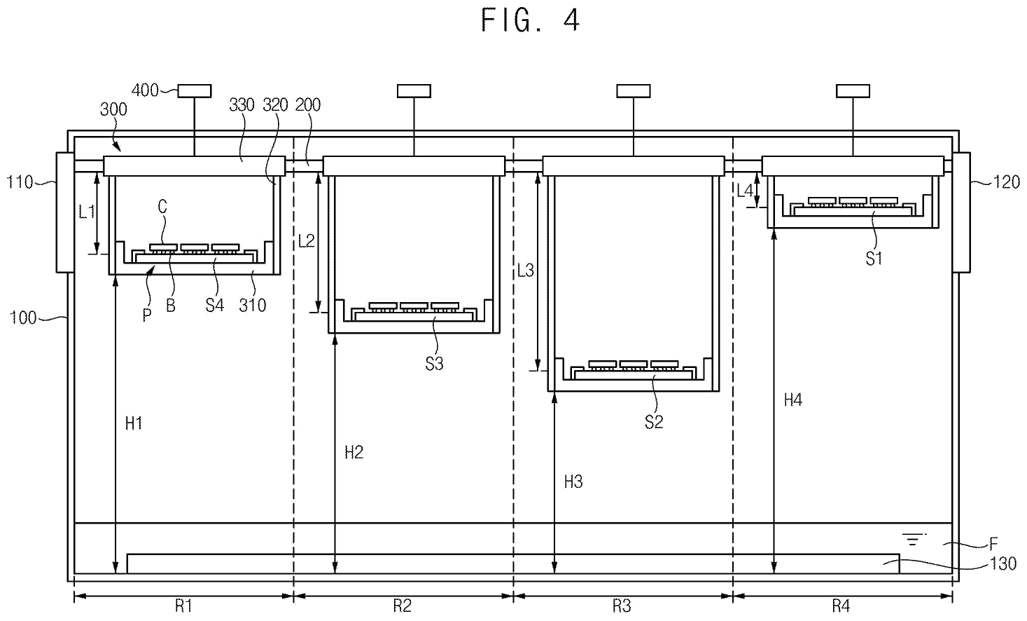

Referring to FIG. 4, after completing the third process on the first substrate S1 in the third region R3, the first substrate S1 may then be moved from the third region R3 to the fourth region R4. The second substrate S2 may be loaded into the empty third region R3. Thus, in an embodiment, while the fourth process may be simultaneously performed on the first substrate S1 in the fourth region R4, the third process may be performed on the second substrate S2 in the third region R3. The third substrate S3 may be loaded into the empty second region R2. The second process may be performed on the third substrate S3 in the second region R2 while the fourth process is performed on the first substrate S1 in the fourth region R4 and the third process is performed on the second substrate S2 in the third region R3.

Further, the stage module 300 may load a fourth substrate S4 into the empty first region R1. Thus, while the second process may be performed on the third substrate S3 in the second region R2, the third process is performed on the second substrate S2 in the third region R3 and the fourth process is performed on the first substrate S1 in the fourth region R4, the first process may be simultaneously performed on the fourth substrate S4 in the first region R1.

According to an embodiment, as the solder reflow process is performed on a substrate, the solder reflow process may also be sequentially performed on the following substrates. Thus, a time of the solder reflow process with respect to all the substrates may be reduced to increase the productivity and process efficiency of the solder reflow process.

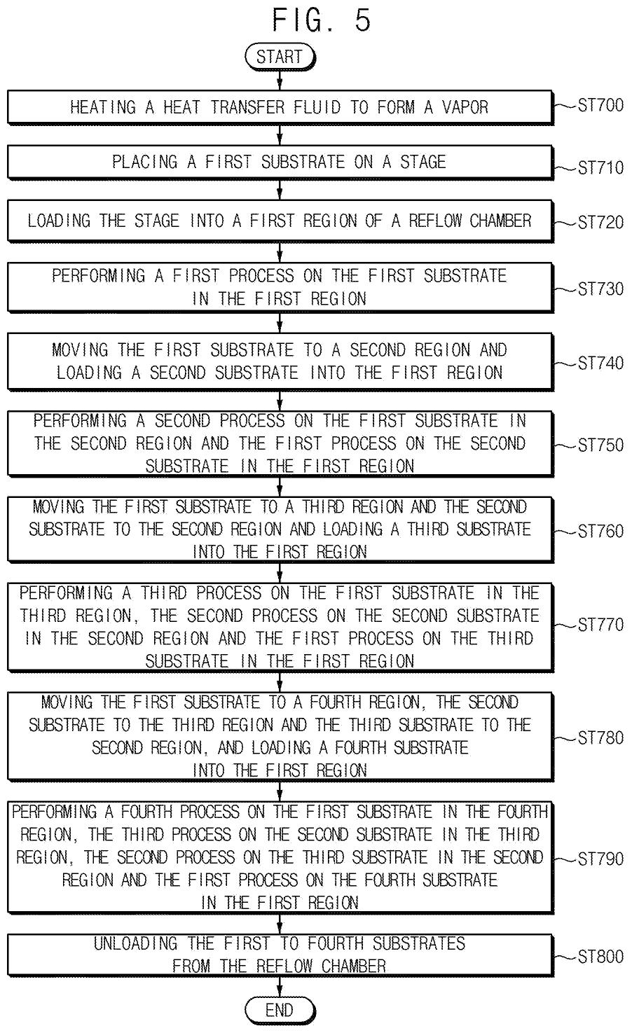

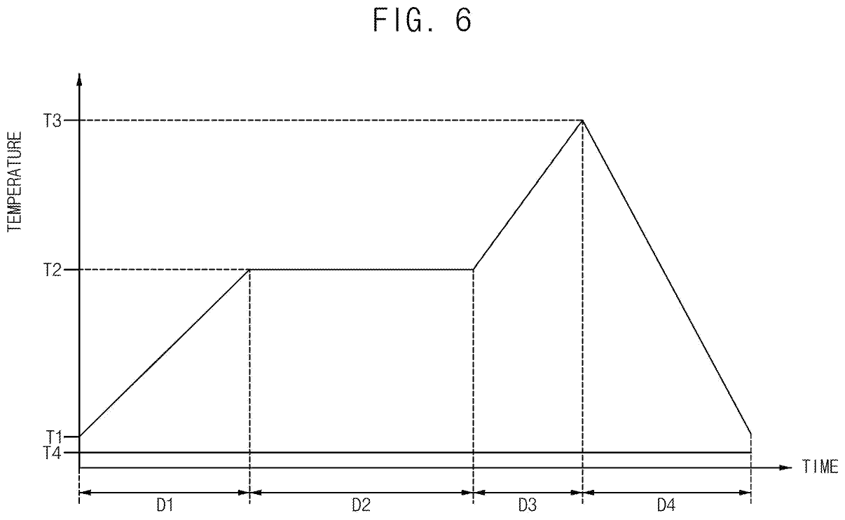

FIG. 5 is a flow chart illustrating a solder reflow method using the solder reflow apparatus in FIG. 1 and FIG. 6 is a timing chart illustrating the solder reflow method in FIG. 5.

Referring to FIGS. 5 and 6, in step ST700, the heater 130 may heat the heat transfer fluid F to generate the vapor from the heat transfer fluid F.

In step ST710, the first substrate S1 with the semiconductor chip may be placed on the stage 310 of the stage module 300.

In step ST720, the horizontal actuator 330 may be moved along the rail 200 to load the stage 310 into the reflow chamber 100 through the loading gate 110. Thus, the first substrate S1 may be loaded into the reflow chamber 100. In an embodiment, the stage 310 may be positioned in the first region R1 of the reflow chamber 100.

In step ST730, the vertical actuator 320 in the first region R1 may descend the first substrate S1 a first length L1 to position the first substrate S1 at the first height H1. The first process may be performed on the solder of the first substrate S1 at the first temperature T1 for a first time D1. For example, the solder of the first substrate S1 in the first region R1 may be dipped into the heat transfer fluid F for the first time D1.

In step ST740, the horizontal actuator 330 may transfer the first substrate S1 to the second region R2 from the first region R1. Simultaneously, the second substrate S2 may be loaded into the first region R1 of the reflow chamber 100 by the following stage module 300.

In step ST750, the vertical actuator 320 in the second region R2 may descend the first substrate S1 the second length L2 to position the first substrate S1 at the second height H2. The second process may be performed on the solder of the first substrate S1 at the second temperature T2 for a second time D2. For example, the solder of the first substrate S1 in the second region R2 may be pre-heated for the second time D2.

Simultaneously, the vertical actuator 320 in the first region R1 may descend the second substrate S2 the first length L1 to position the second substrate S2 at the first height H1. The first process may be performed on the solder of the second substrate S2 at the first temperature T1 for the first time DL. For example, the solder of the second substrate S2 in the first region R1 may be dipped into the heat transfer fluid F for the first time D1.

In step ST760, the horizontal actuator 330 may transfer the first substrate S1 to the third region R3 from the second region R2. Further, the horizontal actuator 330 may transfer the second substrate S2 to the second region R2 from the first region R1. Simultaneously, the third substrate S3 may be loaded into the first region R1 of the reflow chamber 100 by the following stage module 300.

In step ST770, the vertical actuator 320 in the third region R3 may descend the first substrate S1 the third length L3 to position the first substrate S1 at the third height H3. The third process may be performed on the solder of the first substrate S1 at the third temperature T3 for a third time D3. For example, the solder of the first substrate S1 in the third region R3 may be reflowed for the third time D3.

Further, the vertical actuator 320 in the second region R2 may descend the second substrate S2 the second length L2 to position the second substrate S2 at the second height H2. The second process may be performed on the solder of the second substrate S2 at the second temperature T2 for the second time D2. For example, the solder of the first substrate S2 in the second region R2 may be pre-heated for the second time D2.

Simultaneously, the vertical actuator 320 in the first region R1 may descend the third substrate S3 the first length L1 to position the third substrate S3 at the first height H1. The first process may be performed on the solder of the third substrate S3 at the first temperature T1 for the first time D1. For example, the solder of the third substrate S3 in the first region R1 may be dipped into the heat transfer fluid F for the first time D1.

In step ST780, the horizontal actuator 330 may transfer the first substrate S1 to the fourth region R4 from the third region R3. Further, the horizontal actuator 330 may transfer the second substrate S2 to the third region R3 from the second region R2. The horizontal actuator 330 may transfer the third substrate S3 to the second region R2 from the first region R1. Simultaneously, the fourth substrate S4 may be loaded into the first region R1 of the reflow chamber 100 by the following stage module 300.

In step ST790, the vertical actuator 320 in the fourth region R4 may ascend the first substrate S1 the fourth length L4 to position the first substrate S1 at the fourth height H4. The fourth process may be performed on the solder of the first substrate S1 at the fourth temperature T4 for a fourth time D4. For example, the solder of the first substrate S1 in the fourth region R4 may be cooled for the fourth time D4.

Further, the vertical actuator 320 in the third region R3 may descend the second substrate S2 the third length L3 to position the second substrate S2 at the third height H3. The third process may be performed on the solder of the second substrate S2 at the third temperature T3 for the third time D3. For example, the solder of the second substrate S2 in the third region R3 may be reflowed for the third time D3.

The vertical actuator 320 in the second region R2 may descend the third substrate S3 the second length L2 to position the third substrate S3 at the second height H2. The second process may be performed on the solder of the third substrate S3 at the second temperature T2 for the second time D2. For example, the solder of the third substrate S3 in the second region R2 may be pre-heated for the second time D2.

The vertical actuator 320 in the first region R1 may descend the fourth substrate S4 the first length L1 to position the fourth substrate S4 at the first height H1. The first process may be performed on the solder of the fourth substrate S4 at the first temperature T1 for the first time D1. For example, the solder of the fourth substrate S4 in the first region R1 may be dipped into the heat transfer fluid F for the first time D1.

In step ST800, the first to fourth substrates S1, S2, S3 and S4 on which the solder reflow process may be performed may be sequentially unloaded from the reflow chamber 100 through the unloading gate 120.

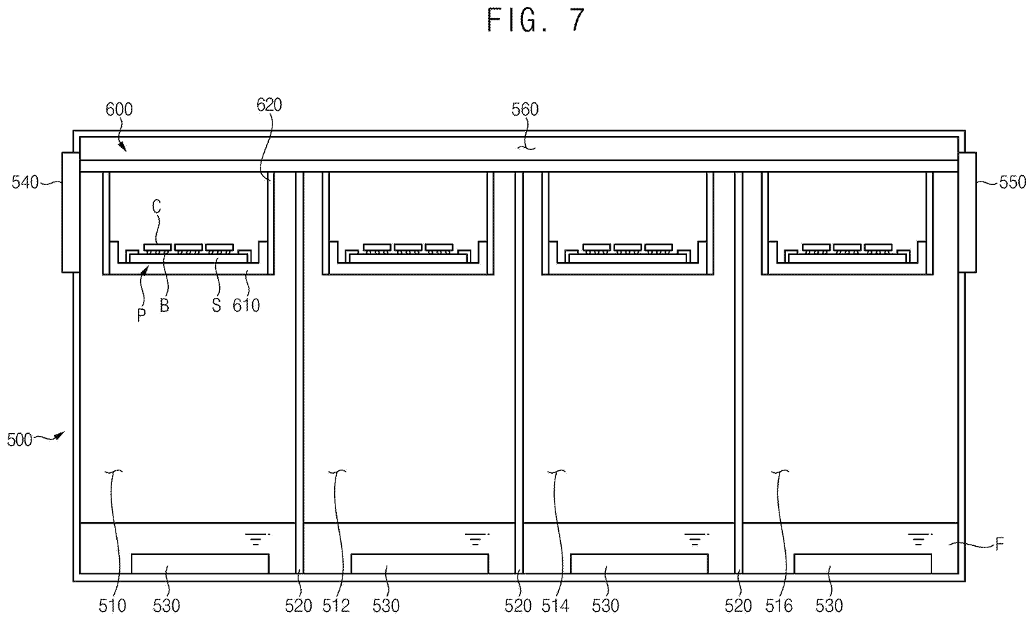

FIG. 7 is a cross-sectional view illustrating a solder reflow apparatus in accordance with an embodiment of the present disclosure.

Referring to FIG. 7, in an embodiment a solder reflow apparatus may include a reflow chamber 500, a plurality of heaters 530, a loading gate 540, an unloading gate 550, an unloading passage 560 and a stage module 600.

The reflow chamber 500 may include a plurality of sub-chambers 510, 512, 514 and 516. At least one partition 520 may be vertically arranged at a middle portion of the reflow chamber 500 to divide the reflow chamber 500 into the sub-chambers 510, 512, 514 and 516. While in an embodiment shown in FIG. 7 the number of the plurality of sub-chambers 510, 512, 514, 516 is four, embodiments of the present disclosure are not necessarily limited thereto. For example, in some embodiments the number of the sub-chambers may be two, three or five or more.

Each of the sub-chambers 510, 512, 514 and 516 may be configured to independently perform the solder reflow process. Each of the sub-chambers 510, 512, 514 and 516 may have a structure and functions substantially the same as the structure and the functions of the reflow chamber 100 in FIG. 1. Thus, any further illustrations with respect to the structure and the functions of the sub-chambers 510, 512, 514 and 516 may be omitted herein for economy of description

The heaters 530 may be arranged in each of the sub-chambers 510, 512, 514 and 516 to heat the heat transfer fluid F. In an embodiment, each of the heaters 530 may be positioned on a bottom surface of each of the sub-chambers 510, 512, 514 and 516. However, embodiments of the present disclosure are not necessarily limited thereto.

The stage module 600 may include a stage 610 and a vertical actuator 620. The stage 610 and the vertical actuator 620 may be substantially the same as the stage 310 and the vertical actuator 320 of an embodiment in FIG. 1, respectively. Thus, any further illustrations with respect to the stage 610 and the vertical actuator 620 may be omitted herein for economy of description.

The loading gate 540 may be arranged at an upper portion of a first sidewall of the reflow chamber 500. The substrate may be loaded into the reflow chamber 500 through the loading gate 540. The unloading gate 550 may be arranged at an upper portion of the second sidewall of the reflow chamber 500 that is opposite to the first sidewall of the reflow chamber 500. After the solder reflow process, the substrate may be unloaded from the reflow chamber 500 through the unloading gate 550.

The unloading passage 560 may be connected between the loading gate 540 and the unloading gate 550. For example, in an embodiment the unloading passage 560 may be extended in an upper region of the reflow chamber 500 from the first sidewall to the second sidewall of the reflow chamber 500. The partition 520 may be connected to a lower surface of the unloading passage 560. Thus, the substrates on which the solder reflow process may be performed in the sub-chambers 510, 512, 514 and 516 may be transferred to the unloading gate 550 through the unloading passage 560.

According to an embodiment, the reflow chamber may be divided into a plurality of the regions. The stage module may sequentially transfer a previous substrate along the rail. Thus, the first to third processes in the reflow process may be sequentially performed on the previous substrate. During the reflow process of the previous substrate, a following substrate may be loaded into the reflow chamber through the rail. Therefore, the reflow process may be performed on the following substrate during performing the reflow process on the previous substrate. As a result, the solder reflow process may have increased productivity by decreasing a time of the solder reflow process.

The foregoing is illustrative of example embodiments and is not to be construed as necessarily limiting thereof. Although a few embodiments have been described, those skilled in the art will readily appreciate that many modifications are possible in embodiments without materially departing from the present disclosure. Therefore, it is to be understood that the foregoing is illustrative of various example embodiments and embodiments of the present disclosure are not necessarily limited to the described embodiments, and that modifications to the disclosed example embodiments, as well as other example embodiments, are intended to be included within the scope of the present disclosure.

What is claimed is:

1. A solder reflow apparatus comprising:
a reflow chamber receiving a heat transfer fluid, the heat transfer fluid transferring heat to a solder for mounting an electronic part on a substrate;
a heater heating the heat transfer fluid in the reflow chamber;
a rail arranged in an upper region of the reflow chamber and extending along a horizontal direction;
a stage module movably connected to the rail and supporting the substrate; and
a controller controlling a positioning of the stage module to move the substrate supported by the stage module to different heights in a vertical direction.

2. The solder reflow apparatus of claim 1, wherein the stage module comprises:
a stage supporting the substrate;
a vertical actuator moving the stage in the vertical direction in response to the controller; and
a horizontal actuator movably connected to the rail, the horizontal actuator moving the stage along the horizontal direction in response to the controller.

3. The solder reflow apparatus of claim 1, wherein the reflow chamber comprises:
first to third regions, wherein:
a first process for dipping the solder in the heat transfer fluid at a first temperature is performed in the first region;
a second process for pre-heating the solder at a second temperature is performed in the second region; and
a third process for reflowing the solder at a third temperature is performed in the third region.

4. The solder reflow apparatus of claim 3, wherein the first temperature is lower than the second temperature and the third temperature is higher than the second temperature.

5. The solder reflow apparatus of claim 3, wherein:
the reflow chamber further comprises a fourth region, wherein a fourth process for cooling the solder at a fourth temperature lower than the first temperature is performed in the fourth region.

6. The solder reflow apparatus of claim 5, wherein:
the stage module in the first region has a first height in response to the controller;
the stage module in the second region has a second height lower than the first height in response to the controller;
the stage module in the third region has a third height lower than the second height in response to the controller; and
the stage module in the fourth region has a fourth height higher than the first height in response to the controller.

7. The solder reflow apparatus of claim 5, further comprising at least one following stage module loaded into the first region after the stage module is moved to the second region from the first region.

8. The solder reflow apparatus of claim 1, wherein the reflow chamber comprises:
a loading gate loading the stage module into the reflow chamber; and
an unloading gate unloading the stage module from the reflow chamber.

9. The solder reflow apparatus of claim 1, wherein:
the substrate comprises a package substrate; and
the electronic part comprises a semiconductor chip.

10. A solder reflow apparatus comprising:
a reflow chamber including a plurality of sub-chambers, each of the plurality of sub-chambers receiving a heat transfer fluid to independently perform a solder reflow process, the heat transfer fluid transferring heat to a solder for mounting an electronic part on a substrate;
heaters heating the heat transfer fluid in the plurality of sub-chambers, respectively;
stage modules arranged in the plurality of sub-chambers, respectively, the stage modules supporting the substrate;
a loading gate loading the substrate into the plurality of sub-chambers;
an unloading gate unloading the substrate from the plurality of sub-chambers; and
an unloading passage extending between the loading gate and the unloading gate.

11. The solder reflow apparatus of claim 10, further comprising vertical actuators moving each of the stage modules in a vertical direction, respectively.

12. A solder reflow method comprising:
heating a heat transfer fluid in a reflow chamber, the heat transfer fluid transferring heat to a solder for mounting an electronic part on a substrate;
positioning the substrate with the solder at a first height in a first region of the reflow chamber to perform a first process of dipping the solder into the heat transfer fluid;
positioning the substrate at a second height lower than the first height in a second region of the reflow chamber to perform a second process of pre-heating the solder; and
positioning the substrate at a third height lower than the second height in a third region of the reflow chamber to perform a third process of reflowing the solder.

13. The solder reflow method of claim 12, wherein the first process is performed at a first temperature, the second process is performed at a second temperature higher than the first temperature, and the third process is performed at a third temperature higher than the second temperature.

14. The solder reflow method of claim 13, wherein the first temperature is in a range of about 25° C. to about 150° C., the second temperature is in a range of about 150° C. to about 200° C., and the third temperature is in a range of about 200° C. to about 230° C.

15. The solder reflow method of claim 13, further comprising positioning the substrate at a fourth height higher than the first height in a fourth region of the reflow chamber to perform a fourth process of cooling the solder.

16. The solder reflow method of claim 15, wherein the fourth process is performed at a fourth temperature lower than the first temperature.

17. The solder reflow method of claim 16, wherein the fourth temperature is in a range of about 20° C. to about 30° C.

18. The solder reflow method of claim 12, further comprising sequentially transferring the substrate to the first region, the second region and the third region.

19. The solder reflow method of claim 18, further comprising loading a following substrate into the first region after moving the substrate to the second region from the first region.

20. The solder reflow method of claim 12, wherein:
the substrate comprises a package substrate; and
the electronic part comprises a semiconductor chip.
